(19) United States
(12) Patent Application Publication
(10) Pub. No.: US 2006/0233037 A1
(43) Pub. Date: Oct. 19, 2006

(54) Method and apparatus for operating electronic semiconductor chips via signal lines

(76) Inventor: Rory Dickman, Graz (AT)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/385,014

(22) Filed: Mar. 20, 2006

Related U.S. Application Data
(63) Continuation of application No. PCT/EP04/10003, filed on Sep. 8, 2004.

(30) Foreign Application Priority Data
Sep. 19, 2003 (DE) DE 103 43 524.7

(51) Int. Cl. G11C 8/00

(52) U.S. Cl. 365/230.03

(57) ABSTRACT

The invention relates to a method for operating electronic semiconductor chips via signal lines, particularly memory chips, where the semiconductor chips are arranged in groups on modules, and where the modules are connected to the signal lines, having the following method steps: a signal quality on the signal lines of the semiconductor chips on the modules during a signal transmission is ascertained and rated using prescribed electrical criteria, semiconductor chips are selected, and the selected semiconductor chips are used on the basis of a result of the rating.

### CROSS-REFERENCE TO RELATED APPLICATIONS

This application is a continuation of co-pending PCT patent application No. PCT/EP 2004/010003, filed Sep. 8, 2004, which claims the benefit of German patent application serial number DE 103 43 524.7, filed Sep. 19, 2003. Each of the aforementioned related patent applications is herein incorporated by reference in its entirety.

### BACKGROUND OF THE INVENTION

1. Field of the Invention

The invention relates to a method and an apparatus for operating electronic semiconductor chips, particularly memory chips, via signal lines.

2. Description of the Related Art

Electronic systems with a central processor have an ever greater requirement for electronic main memory today. For this purpose, memory systems of modular design are normally provided, with the memory modules having a multiplicity of electronic memory chips arranged on them. The memory modules are connected to signal lines which form a signal line bus which is connected to a memory control unit (memory controller). The memory control unit is used to actuate the individual modules so that the modules can interchange data with individual components of the electronic systems.

Conventional memory systems usually have a rigid operating scheme which provides for just a single one of the modules ever to obtain access to the signal line bus at a defined time and to write data to the signal line bus or to read in said data from said signal line bus in this way. In this manner, all the modules obtain access to the common signal line bus at different times.

On the basis of measurements on the signal lines during signal transmission operations, it has been found that various parasitic properties within the electronic systems can disadvantageously influence signal quality on the signal line bus. These undesirable parasitic properties may be attributable, by way of example, to unfavorable conductor track runs on the individual modules and/or on printed circuit boards with slots for the modules. In addition, individual data pins on packages for the semiconductor chips may have different operating characteristics on account of the parasitic effects. The aforementioned rigid operating scheme for the individual memory modules means that the parasitic effects can accumulate in an undesirable manner. These may disadvantageously also be additionally worsened by radio-frequency interference and/or by inductive and capacitive coupling between the individual components in the memory systems. This can result in an effective data throughput via the signal line bus being reduced in an undesirable manner.

This results from the fact that individual signal lines in the signal line bus have an impaired signal transmission characteristic in comparison with other signal lines. Erroneous data transmissions and their necessitated complex error correction are a disadvantageous and undesirable consequence of the parasitic effects outlined above.

### SUMMARY OF THE INVENTION

Embodiments of the present invention provide a method and an apparatus for improved operation of electronic semiconductor chips via signal lines.

A method based on one embodiment of the present invention is provided for operating electronic semiconductor chips, particularly memory chips, via signal lines. In this case, the semiconductor chips are arranged in groups on modules, with the modules being connected to the signal lines. The method comprises the following method steps. First, a signal quality on the signal lines of the semiconductor chips on the modules during a signal transmission is ascertained and rated using prescribed electrical criteria. Second, the semiconductor chips are selected. Third, the selected semiconductor chips are used on the basis of a result of the rating.

In this way, a signal line quality ascertained under real operating conditions for the memory modules can be used to select and use semiconductor chips for signal transmission. This advantageously allows semiconductor chips to be selected and used flexibly in a manner which is essentially dependent only on the signal line quality. The previously described conventional rigid operating scheme for the individual memory chips on the memory modules is made more flexible as a result and can improve an operating characteristic for the signal line bus in this way.

In one preferred development of the inventive method, the method steps are carried out periodically during the signal transmission on the signal lines. This allows permanent optimization of the selection of the semiconductor chips used for the signal transmission during operation of the memory modules, which allows the response of the signal line bus to be improved further.

An apparatus based on one embodiment of the invention is provided for operating electronic semiconductor chips via signal lines, particularly memory chips. In this case, the semiconductor chips are arranged in groups on modules, with the modules being connected to the signal lines. The apparatus has a control device for selecting semiconductor chips on the basis of prescribed electrical criteria. The control device is used to ascertain and rate a signal quality on the signal lines of the semiconductor chips on the modules during a signal transmission.

The inventive apparatus can be used for individually selecting the memory chips used for signal transmission and therefore to reduce any influence of the previously described parasitic effects on the operating characteristic of the signal line bus.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows an arrangement of four memory modules with nine respective memory chips;

FIG. 2 shows an arrangement of four memory modules connected to one another by a signal line bus, with the signal line bus being connected to a control device;

FIG. 3 shows an arrangement comprising four memory modules, connected to one another by the signal line bus, with a control device according to one embodiment of the invention;

FIG. 4 shows a basic illustration of electrical signals on the signal lines with exemplary electrical selection criteria;

FIG. 5 shows a basic flowchart of a sequence in a method according to one embodiment of the invention; and

FIG. 6 shows an electronic computer system to which one embodiment of the invention is applied.

### DETAILED DESCRIPTION OF THE PREFERRED EMBODIMENT

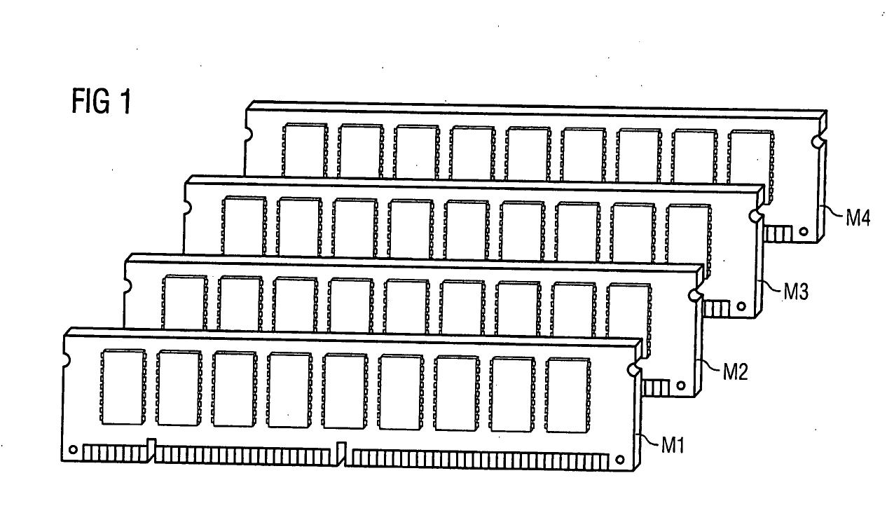

FIG. 1 shows four modules M1 to M4 with nine respective semiconductor chips on each module, which may be in the form of memory chips. In this case, the memory chips may be in the form of SDR-SDRAMs (single data rate synchronous dynamic memory chips) or DDR-SDRAMs (double data rate synchronous dynamic random access memory), which are arranged on the modules M1 to M4 on one side (single inline memory module/SIMM) or on two sides (dual inline memory module/DIMM). FIG. 1 shows, by way of example, four modules M1 to M4 in the form of dual inline memory modules. A total number of the modules M1 to M4 can be used as a main memory in an electronic computer system, for example. In this case, the modules M1 to M4 may be plugged into slots on a printed circuit board (not shown) using electrical connections provided for this purpose. A signal line bus (not shown) to which the modules M1 to M4 are connected and which connects the modules M1 to M4 to one another is provided for interchanging data between the modules M1 to M4 and a central processor in the electronic computer system. On account of the memory chips having different physical arrangements on the modules M1 to M4, parasitic effects of connection pins on the memory chips may have a disadvantageous effect on a response from individual signal lines in the signal line bus while the memory chips are in working operation.

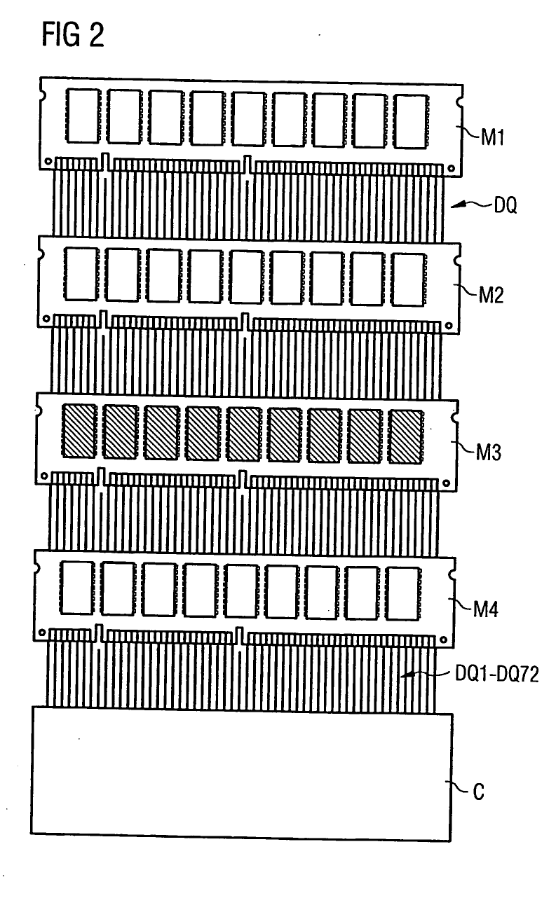

FIG. 2 shows four modules M1 to M4 which are connected to one another by signal lines DQ1 to DQ72, the signal lines DQ1 to DQ72 forming the signal line bus DQ. The signal line bus DQ connects the modules M1 to M4 to a control device C which is provided for actuating the semiconductor chips on the individual modules M1 to M4. In this case, provision is conventionally made for just memory chips on a single one of the modules M1 to M4 ever to be actuated or selected by the control device C at a defined time, with exclusively the semiconductor chips on the selected module M1 to M4 being provided for data interchange via the signal line bus DQ.

In FIG. 2, this conventional manner of working operation of the modules M1 to M4 is indicated by virtue of all the memory chips on the module M3 being shaded. This means that at the operating time shown in FIG. 2, only the memory chips on the module M3 are connected to the signal line bus DQ. The signal line bus DQ may have 72 signal lines DQ1 to DQ72, for example. If the memory chips are in an ×8 organization as shown in FIG. 2, nine memory chips per module M1 to M4 are required for fully occupying the signal line bus DQ with signal lines DQ1 to DQ72. In this case, eight connection pins on nine memory chips are respectively connected to the signal line bus DQ at a defined time. By contrast, an ×4 organization for the memory chips would require eighteen memory chips which each have four connection pins connected to the signal line bus DQ at the same time. This ensures full occupation of the signal line bus DQ with signal lines DQ1 to DQ72, as required during operation of the signal line bus DQ.

In conventional methods, selection of the memory chips during working operation of the main memory is therefore performed on the basis of a rigid operating scheme in module-dependent fashion. This allows disadvantageous parasitic effects, such as inductive or capacitive coupling between individual elements of the main memory, and/or radio-frequency interference signals injected onto the signal lines DQ0 to DQ72, which interference signals are always present on account of the system, to accumulate disadvantageously to produce a parasitic overall effect. This overall effect can significantly impair a signal transmission response on individual signal lines of the signal line bus DQ. This impairment can be attributed to the fact that connection pins on memory chips which are influenced particularly unfavorably on account of the outlined parasitic effects and therefore exhibit a particularly severe reduction in performance are connected to the signal line bus as a result of the need for the exclusive selection of memory chips on a single memory module M1 to M4. Erroneous transmissions which result from this on the signal line bus DQ can disadvantageously lead to signal transmissions being repeated. This can disadvantageously and significantly reduce a data rate transmitted on the signal line bus DQ.

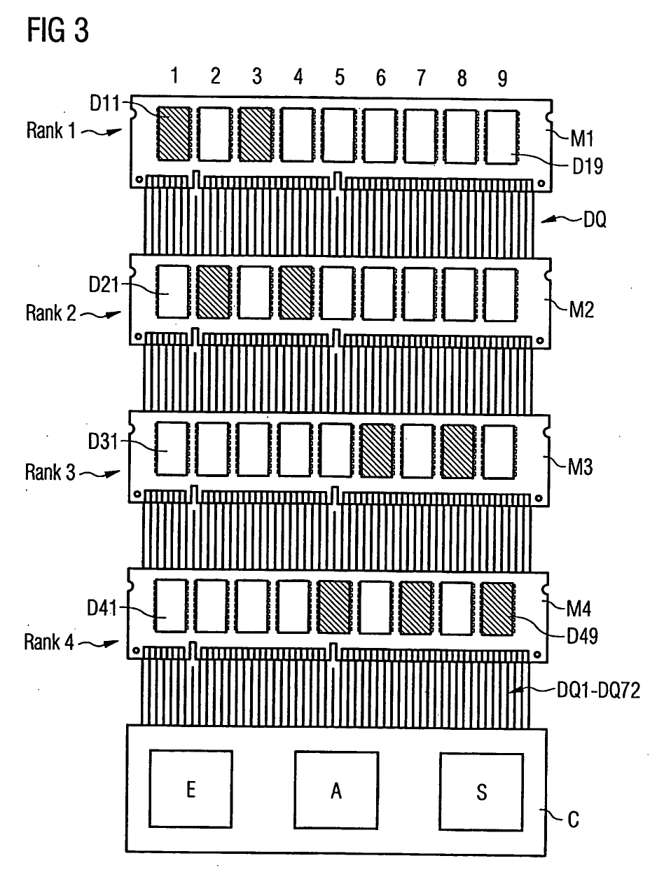

FIG. 3 shows an arrangement comprising four modules M1 to M4, connected to one another by the signal line bus DQ, with an embodiment of the inventive control device C. The control device C has a rating unit S, an activation unit A and a compilation unit E. The signal line bus DQ is conventionally provided for linking and connecting the individual modules M1 to M4 and is also connected to the inventive control device C. Arranged on the individual modules M1 to M4 are respective groups of memory chips which are called “ranks”. A rank defines a group of memory chips on a module which (group) fully occupies the signal line bus DQ with connections. The individual memory chips in the ranks can be actuated by CRS (Chip Rank Select) selection lines (not shown in FIG. 3), with each of the memory chips in a rank being able to be actuated by a separate selection line. FIG. 3 reveals that the memory chips on the modules or in the ranks can be localized by a numerical index. In this case, a first digit defines a rank index specifying a rank. A second digit defines a column index specifying a local arrangement of the memory chip within the respective rank. By way of example, an index 11 defines a first memory chip D11 in column 1 of rank 1. An index 49 defines a memory chip D49 in column 9 of rank 4, for example.

As a first step in the sequence of the method according to one embodiment of the invention, an activation unit A is used to activate a rating unit S. The rating unit S is provided for rating a signal line quality for the signal lines DQ1 to DQ72, with the individual signal lines DQ1 to DQ72 being rated by the rating unit S using prescribed electrical parameters. As the result of this rating operation, a compilation unit E connects selected memory chips to the signal line bus DQ in module-independent fashion. This means that, depending on the result of the preceding rating procedure, memory chips from different modules M1 to M4 can be connected to the signal line bus. The organizational form (for example ×4 or ×8) of the memory chips, which was explained with reference to FIG. 2, is maintained unchanged in this case. A signal line bus DQ connected up in this manner may have a significantly improved signal transmission response in comparison with the conventional rigidly connected signal line bus DQ, in which exclusively memory chips on a single module M1 to M4 are connected to the signal line bus DQ.

The way in which the inventive method works is described in more detail below using selected memory chips (shown in FIG. 3) on the modules M1 to M4. Each of the modules M1 to M4 has nine memory chips. A first memory chip D11 is arranged on the module M1. A second memory chip D21 is arranged on the module M2. A third memory chip D31 is arranged on the module M3, and a fourth memory chip D41 is arranged on the module M4. Each of the memory chips D11, D21, D31, D41 is connected to identical signal lines DQ1 to DQ72 in the signal line bus DQ during working operation. In line with the organizational structure of the memory chips, however, only one of the memory chips D11, D21, D31, D41 can be connected to the signal line bus DQ at a defined time.

In the sequence of the method according to one embodiment of the invention, the rating unit S rates those signal lines DQ1 to DQ72 to which a respective one of the memory chips D11, D21, D31, D41 is connected. In this case, by way of example, the first memory chip D11 is first connected to the signal line bus DQ and the corresponding signal lines DQ0 to DQ72 in the signal line bus DQ are rated by the rating unit S in terms of quality using prescribed electrical criteria. After that, the first memory chip D11 is disconnected from the signal line bus DQ, and the signal line quality is ascertained in a similar manner before using the second memory chip D21 connected to the signal line bus DQ. The outlined sequence is repeated until all of the memory chips D11, D21, D31, D41 have been connected at least once to the signal line bus DQ and the signal lines DQ1 to DQ72 in the signal line bus DQ which are connected to associated connection pins of the memory chips D11, D21, D31, D41 have been evaluated. As the result of the rating operation carried out, that one of the memory chips D11, D21, D31, D41 whose connection to the signal line bus DQ involved the prescribed electrical criteria on the relevant signal lines DQ1 to DQ72 being met best is finally connected to the signal line bus DQ for working operation.

The principle of the invention has been explained by way of example for one of the memory chips D11, D21, D31, D41 on the modules M1 to M4. It goes without saying that the outlined principle is implemented for all the memory chips on the modules M1 to M4.

FIG. 3 therefore basically indicates that memory chips on various modules M1 to M4 can be used for fully occupying the signal line bus DQ. Those memory chips whose connection pins are connected to the signal line bus DQ are shown shaded in the figure. It can be seen that the nine memory chips required for fully occupying the signal line bus DQ are arranged on different modules M1 to M4. As the result of the rating and selection according to one embodiment of the invention, signal lines DQ1 to DQ72 with the best possible performance are therefore advantageously used for the signal line bus DQ. Depending on the signal quality on the signal lines DQ1 to DQ72, memory chips on a single module or on a plurality of modules M1 to M4 are connected to the signal line bus DQ.

The control device C can also stipulate a bus width used for the signal transmission via the signal line bus DQ. In this case, a 72-bit signal line bus DQ may be provided with 8 bits, for example, for error correction using an ECC (error correcting code) method known in the prior art. The ECC method is an intelligent error recognition method which can be used to correct a subset of disturbed characters on the basis of formation laws for the characters. The method involves a plurality of check bits being added to the useful bits, from which the correct character is ascertained at a receiving station on the basis of the probability principle.

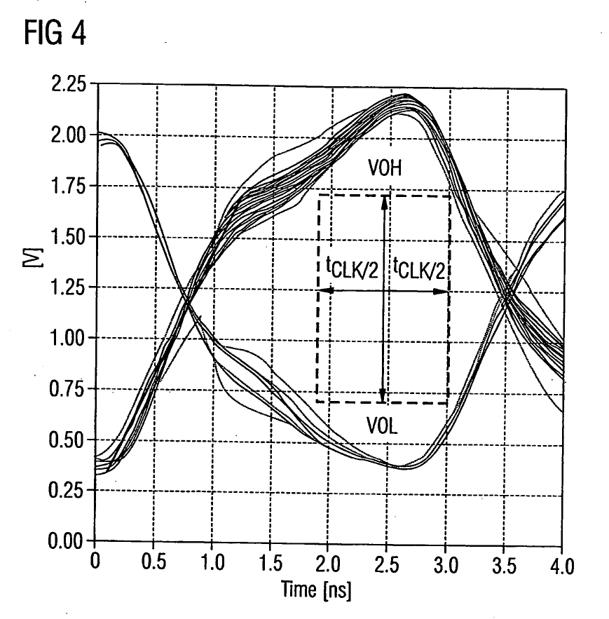

FIG. 4 shows a basis qualitative voltage/time graph with different profiles for signals which are transmitted on the signal lines DQ0 to DQ72 during working operation of the modules M1 to M4. Within the data eye shown in the figure, electrical selection criteria which can be used for the inventive method are shown in basic form. In this case, the signal qualities can be rated using, by way of example, electrical voltage levels (VOH, VOL), and/or a period duration or clock frequency (t_{CLK/2}), and/or a rise speed and/or a duty cycle for the signals. The electrical criteria shown in FIG. 4 are to be understood merely by way of example and can naturally be complemented or replaced by further electrical criteria.

FIG. 5 uses a basic flowchart to show a sequence for an exemplary embodiment of the inventive method. In a step S1, the activation unit A is used to activate the rating unit S, which performs the rating for the signal lines DQ0 to DQ72. In a step S2, the signal lines DQ0 to DQ72 are rated by the rating unit S using the prescribed electrical criteria. In a step S3, the compilation unit E is used to select the memory chips on the basis of the previous rating. In a step S4, the selected memory chips are used.

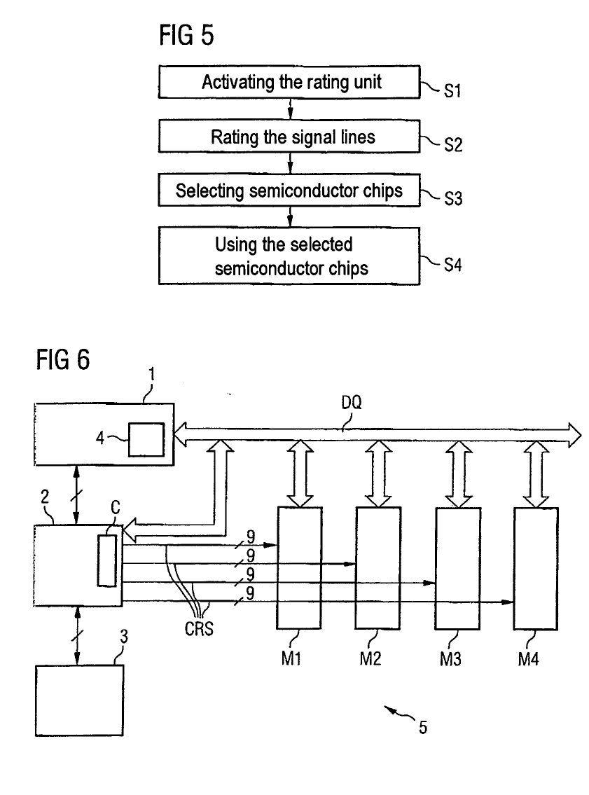

FIG. 6 shows a highly simplified, basic block diagram of an electronic computer system 5 for which the invention can be used. A central processor 1 is connected to a memory control unit 2 which contains an embodiment of the inventive control device C. It is also conceivable for the control device C to be arranged within the central processor 1 or in a separate device in the computer system 5. The memory control unit 2 is connected to a memory or storage device 3. By way of example, the memory/storage device 3 may be in the form of a hard disk memory, but other implementation options are also conceivable. The modules M1 to M4 are connected to the central processor 1 and to the memory control unit 2 and can interchange data with the connected units via the signal line bus DQ. Selection lines CRS connect the memory control unit 2 to the individual modules M1 to M4. The selection lines CRS can be used by the memory control unit 2 to select all the memory chips on the individual modules M1 to M4 in module-independent fashion. To this end, a separate selection line is provided for each memory chip on the modules M1 to M4. In FIG. 6, nine memory chips (not shown) are arranged for each module M1 to M4, so that each module M1 to M4 is therefore provided with nine selection lines CRS for actuating all the memory chips for each module M1 to M4.

The text below uses two different application scenarios to describe how the invention can be used for the computer system 5 shown in FIG. 6.

Scenario 1:

By way of example, provision may be made for a minimal operating system (BIOS) implemented within the central processor 1 to evaluate the main memory available in the modules M1 to M4 while the computer system 5 is starting up. In this case, during startup, the memory physically available in the modules M1 to M4 is partitioned to form a virtual memory, with the virtual memory corresponding to a map of the physical memory in a linear address space. This ensures a unique association between the main memory available in the memory modules M1 to M4 and the virtual memory. Said partitioning is known per se and is not the subject matter of the present invention. The linear address space obtained as the result of the partitioning performed is stored in a management unit 4 which is arranged within the central processor 1.

Furthermore, while the computer system 5 is starting up, the inventive method is carried out merely once using the inventive control device C. The module-independent connection of memory chips to the signal line bus DQ which is carried out in the process continues unchanged for the rest of the operation of the computer system 5. The inventive method is not carried out again until the computer system 5 is next started up. Using the linear address space stored in the management unit 4, the central processor 1 is able to associate the selection of the memory chips which is configured during the inventive rating operation with the individual modules M1 to M4 correctly during working operation.

Scenario 2:

Unlike in scenario 1, in this case the inventive method is carried out a plurality of times. For this purpose, the memory/storage device 3 is used in addition to the variant described above in order to ensure data interchange between the central processor 1 and the memory/storage device 3 at a time at which the memory chips are rated and selected again according to embodiments of the invention. For this purpose, the entire content of the main memory available in the modules M1 to M4 is buffer-stored in the memory/storage device 3 before any reselection of the memory chips. The result of the respective further inventive rating is sent from the control device to the central processor 1, which stores the result in the management unit 4. In this way, the central processor 1 can perform the data interchange with the modules M1 to M4 via the signal line bus DQ which is currently connected up in each case.

A frequency for the inventive rating or configuration of the signal line bus DQ may advantageously be variable. Thus, by way of example, it is conceivable for the inventive rating of the signal line bus DQ to be performed in a background process which is parallel to the working operation. The memory chips are then compiled on the basis of the rating in the time in which the memory/storage device 3 is ensuring data interchange. It is also conceivable for the inventive method to be carried out in times in which there is currently no data interchange taking place between the modules M1 to M4 and the central processor 1 or the memory control unit 2. It is also conceivable for the inventive method to be carried out after a respective defined number of data interchange cycles on the signal line bus DQ.

In this exemplary application, the memory/storage device 3 is therefore utilized to ensure data integrity in phases of the operation of the computer system 5 in which inventive reselection of the memory chips is performed. In addition, it is prohibited for reasons of data integrity for inventive reselection of the memory chips to be carried out while signal transmission is currently being performed. This means that the changeover to the newly configured signal line bus DQ needs to be performed in a defined manner.

The invention in scenario 2 can therefore be considered to be an adaptive method which can be used, advantageously, to adapt the signal line bus DQ to changing operating conditions in the computer system 5 in the best possible manner.

It is considered to be a particular advantage of the present invention that after the inventive method has been carried out, the signal transmission is performed using a signal line bus DQ which has the best possible performance and which is compiled from signal lines DQ0 to DQ72 which meet the prescribed electrical criteria in the best way. This advantageously allows a considerable increase in a data throughput between the individual components of the electronic computer system 5.

The individual aspects of the invention which are disclosed in the description, in the patent claims and in the figures may be fundamental to the invention in any combination.

While the foregoing is directed to embodiments of the present invention, other and further embodiments of the invention may be devised without departing from the basic scope thereof, and the scope thereof is determined by the claims that follow.

What is claimed is:

1. A method for operating a plurality of semiconductor chips disposed in a plurality of modules, comprising:
ascertaining a signal line quality of a plurality of signal lines which connect the respective semiconductor chips on the plurality of modules during a signal transmission;
rating the signal line quality of the plurality of signal lines, based on prescribed electrical criteria for electrical signals transmitted on the signal lines, utilizing a rating device; and
selecting respective semiconductor chips for usage based on a result of the ratings.

2. The method of claim 1, further comprising:
repeating the steps periodically during the signal transmission on the signal lines.

3. The method of claim 1, wherein the prescribed electrical criteria are defined by electrical voltage levels of signals transmitted on the signal lines.

4. The method of claim 1, wherein the prescribed electrical criteria are defined by time profiles of signals transmitted on the signal lines.

5. The method of claim 1, wherein the prescribed electrical criteria are adapted based on a defined number of data interchange cycles on the signal lines.

6. The method of claim 5, wherein the signal lines which have the signal line quality which best meet the criteria are respectively used for a data interchange cycle.

7. The method of claim 1, further comprising:
selecting signal lines for usage based on the result of the rating.

8. An apparatus for operating a plurality of semiconductor chips disposed in a plurality of modules, comprising:
a rating device configured to ascertain and rate a signal line quality for the signal lines which connect the plurality of semiconductor chips on the plurality of modules based on prescribed electrical criteria for electrical signals transmitted on the signal lines during a signal transmission; and
a compilation device for selecting respective semiconductor chips for usage based on a result of the ratings.

9. The apparatus of claim 8, wherein the prescribed electrical criteria are defined by electrical voltage levels of signals transmitted on the signal lines.

10. The apparatus of claim 8, wherein the prescribed electrical criteria are defined by time profiles of signals transmitted on the signal lines.

11. The apparatus of claim 8, further comprising:
an activation unit for activating the rating device.

12. The apparatus of claim 11, wherein the rating device is provided for ascertaining a quality for signals transmitted on the signal lines with respect of the criteria, following activation by the activation unit.

13. The apparatus of claim 8, wherein the rating device and the compilation device are included in a control device.

14. The apparatus of claim 13, wherein the control device is configured for selecting the signal lines for operation.

15. The apparatus of claim 8, wherein the plurality of semiconductor chips comprises memory chips, wherein each module comprises a memory module having a group of memory chips, and wherein each respectively ordered memory chip on different memory modules are connected to a respective signal line of a signal bus connecting the memory modules.

16. An apparatus, comprising:
a plurality of memory modules connected via a signal bus, each memory module comprising a plurality of memory chips disposed in sequence, each memory chip of the same order in the sequence being selectably connectable to a respective plurality of signal lines in the signal bus; and
a control device comprising:
a rating device configured to ascertain and rate a signal line quality for the respective plurality of signal lines which connect the respective plurality of memory chips on the plurality of modules based on prescribed electrical criteria for electrical signals transmitted on the respective plurality of signal lines during a signal transmission; and
a compilation device for selecting respective memory chips for usage based on a result of the ratings.

17. The apparatus of claim 16, wherein the control device further comprises an activation unit configured to activate the rating device once during initial start up of operation of the apparatus.

18. The apparatus of claim 16, wherein the control device further comprises an activation unit configured to activate the rating device periodically during operation of the apparatus to provide updated rating results, and wherein the compilation device is configured to periodically re-select respective memory chips for usage based on the updated rating results.

19. The apparatus of claim 16, further comprising:
a memory control unit having the control device; and
a plurality of groups of chip rank select (CRS) selection lines respectively connected between the memory modules and the memory control unit, wherein the memory control unit provides signals via the CRS selection lines for selecting the respective memory chips for usage.

20. The apparatus of claim 19, further comprising:
a central processor connected to communicate with the memory modules via the signal bus, the central processor also connected to communicate with the memory controller, wherein the central processor comprises a management unit for storing the result of the rating of the signal line quality of the respective plurality of signal lines connected to the respective memory chips; and
a storage device connected to the memory controller, wherein the storage device is configured to temporarily store contents of the plurality of memory modules while the plurality of the signal lines are being rated.
